(19) United States
(12) Patent Application Publication
(10) Pub. No.: US 2012/0141942 A1
(43) Pub. Date: Jun. 7, 2012

(54) METHOD OF PREPARING LITHOGRAPHIC PRINTING PLATES

(76) Inventors: Domenico Balbinot, Osterode am Harz (DE); Mathias Jarek, Bad Gandersheim (DE); Jianbing Huang, Trumbull, CT (US); Ting Tao, Fort Collins, CO (US); Christopher D. Simpson, Osterode (DE)

(21) Appl. No.: 12/959,432

(22) Filed: Dec. 3, 2010

(51) Int. Cl. G03F 7/20

(52) U.S. Cl. 430/302

(57) ABSTRACT

Lithographic printing plates are prepared by imaging and developing negative-working lithographic printing plate precursors that include certain particulate polymeric binders in the photosensitive imageable layer. Such particulate polymeric binders are poly(urethane-acrylic) hybrids. Development is carried out using a working strength developer that includes one or more organic solvents in a total amount of at least 7 weight % and an anionic surfactant in an amount of at least 5 weight %.

### FIELD OF THE INVENTION

This invention relates to a method for preparing lithographic printing plates from negative-working lithographic printing plate precursors using organic solvent-containing working strength developers.

### BACKGROUND OF THE INVENTION

In lithographic printing, ink receptive regions, known as image areas, are generated on a hydrophilic surface. When the surface is moistened with water and ink is applied, the hydrophilic regions retain the water and repel the ink the ink receptive regions accept the ink and repel the water. The ink is then transferred to the surface of suitable materials upon which the image is to be reproduced. In some instances, the ink can be first transferred to an intermediate blanket that in turn is used to transfer the ink to the surface of the materials upon which the image is to be reproduced.

Lithographic printing plate precursors useful to prepare lithographic (or offset) printing plates typically comprise one or more imageable layers applied over a hydrophilic surface of a substrate (or intermediate layers). The imageable layer(s) can comprise one or more radiation-sensitive components dispersed within a suitable binder. Following imaging, either the exposed regions or the non-exposed regions of the imageable layer(s) are removed by a suitable developer, revealing the underlying hydrophilic surface of the substrate. If the exposed regions are removed, the element is considered as positive-working. Conversely, if the non-exposed regions are removed, the element is considered as negative-working. In each instance, the regions of the imageable layer(s) that remain are ink-receptive, and the regions of the hydrophilic surface revealed by the developing process accept water or aqueous solutions (typically a fountain solution), and repel ink.

“Laser direct imaging” methods (LDI) have been known that directly form an offset printing plate or printing circuit board using digital data from a computer, and provide numerous advantages over the previous processes using masking photographic films. There has been considerable development in this field from more efficient lasers, improved imageable compositions and components thereof.

Various radiation-sensitive compositions are known for use in negative-working lithographic printing plate precursors as described for example in U.S. Pat. No. 6,309,792 (Hauck et al.), U.S. Pat. No. 6,893,797 (Munnelly et al.), U.S. Pat. No. 6,727,281 (Tao et al.), U.S. Pat. No. 6,899,994 (Huang et al.), and U.S. Pat. No. 7,429,445 (Munnelly et al.), U.S. Patent Application Publications 2002/0168494 (Nagata et al.), 2003/0118939 (West et al.), and EP Publications 1,079,276A2 (Lifka et al.) and 1,449,650A2 (Goto et al.).

U.S. Pat. No. 6,794,104 (Tashiro) describes lithographic printing plate precursors containing particulate materials including particulate thermosetting resins.

WO 2008/036170 (Yu et al.) describes the use of particles of poly(urethane-acrylic) hybrids in negative-working radiation-sensitive compositions for lithographic printing plate precursors. These particulate materials are used as binder materials and provide improved resistance to press chemicals, shelf stability, and run length. Upon imaging, such precursors can be developed using water-miscible and water-soluble solvent-containing working strength developers such as 980 Developer (3.82 weight % of phenoxyethanol), 955 Developer (3.7 weight % of benzyl alcohol), D29 Developer (0.4 weight % of phenoxyethanol and 4 weight % of benzyl alcohol), and 956 Developer (4.58 weight % of phenoxyethanol) that was used in all of the working examples. WO 2008/036170 also mentions a “2 in 1 Developer” but the composition of this solution is not publically known. ND-1 Developer concentrate can also be used but it must be diluted to 3.8 weight % of benzyl alcohol for use.

Another commercial product supplied by Fuji in Japan is Fuji DN-5H developer concentrate that contains 3-7 weight % of benzyl alcohol, but it must be diluted to at least one-half strength before use in a processing step. Thus, the working strength version of the Fuji DN-5H developer concentrate would generally contain benzyl alcohol at a level of 1.5-3 weight %.

While the precursors described in WO 2008036170 have demonstrated the described advantages, we discovered a new problem that components of such precursors tend to form sludge in commonly used developer compositions, thus hindering the operation of automatic processing equipment and making it difficult to clean such equipment at the end of a processing cycle when “used” developer is removed and “fresh” developer is added. As a result, the developers in the processing equipment must be changed frequently, leading to large developer consumption and the generation of a large amount of waste liquids (“used” developer), leading to higher costs and negative effects on the environment. Therefore, we found that there is a need to find a processing method for such precursors that does not exhibit these problems without any loss in the other desired attributes of long shelf life and durability for long press runs.

### SUMMARY OF THE INVENTION

This invention provides a method of providing a lithographic printing plate comprising:

A) imagewise exposing a negative-working lithographic printing plate precursor having a hydrophilic substrate and an imageable layer disposed on the hydrophilic substrate, to provide exposed and non-exposed regions in the imageable layer of the imagewise exposed precursor,

the imageable layer comprising a free radically polymerizable component, an initiator composition that provides free radicals upon imagewise exposure, a radiation absorbing compound, and a particulate non-reactive poly(urethane-acrylic) hybrid, and

B) with or without a preheat step, processing the imagewise exposed precursor with a working strength developer comprising one or more organic solvents in a total amount of at least 7 weight % and an anionic surfactant in an amount of at least 5 weight %, to remove the non-exposed regions in the imageable layer.

We have discovered that the method of this invention exhibits reduced sludge in the processing equipment without loss of desired shelf life and long press runs. Thus, developer waste is reduced.

These advantages are achieved by the combination of the use of specific particulate polymer binders in the imageable layer of the negative-working lithographic printing plate precursor, and development of the imaged precursors using a working strength developer having a relatively higher amount of one or more organic solvents (a total of at least 7 weight % of such solvents). Lower amounts of the organic solvents fail to solve the noted problems. Moreover, the use of developers with lower amounts of organic solvents to process precursors having different polymeric binders provide desired development, but the resulting printing plates exhibit “woodgrain”, insufficient shelf life, or insufficient run length (press run). Thus, both of the noted features (higher organic solvent and specific particulate polymer binders) are used in the method of this invention.

### DETAILED DESCRIPTION OF THE INVENTION

### Definitions

Unless the context indicates otherwise, when used herein, the terms “negative-working lithographic printing plate precursor”, “lithographic printing plate precursor”, “printing plate precursor”, and “precursor” are meant to be references to embodiments of the present invention.

In addition, unless the context indicates otherwise, the various components described herein such as “infrared absorbing compound”, “co-initiator”, “free radically polymerizable component”, “particulate non-reactive polyurethane-acrylic) hybrid”, “polymeric binder”, and similar terms also refer to mixtures of such components. Thus, the use of the articles “a”, “an”, and “the” is not necessarily meant to refer to only a single component.

Moreover, unless otherwise indicated, percentages refer to percents by total dry weight, for example, weight % based on total solids of either an imageable layer or radiation-sensitive composition. Unless otherwise indicated, the percentages can be the same for either the dry imageable layer or the total solids of radiation-sensitive composition.

The term “developer” used in the practice of the method of this invention refers to the processing composition (fluid) that is brought into contact with the imaged lithographic printing plate precursor during the processing step. Some commercial developer concentrates must be diluted one or more times prior to their use in the processing step, and are therefore not developers according to the present invention. For clarification purposes, the term “working strength” is used with the term “developer” to provide explicit distinction between developers used in the processing step and developer concentrates. Thus, in some literature, the commercial name, such as ND-1, is used with the term “developer” to identify a mixture of the commercially available concentrate (ND-1) with water. The developer used in this invention is not considered a concentrate.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached.

One example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Imaging Lithographic Printing Plate Precursors

During use, the lithographic printing plate precursor is exposed to a suitable source of exposing radiation depending upon the second infrared radiation absorbing compound present in the radiation-sensitive composition to provide specific sensitivity that is at a wavelength of at least 700 and up to and including 1400 nm, or at least 750 and up to and including 1250 nm.

For example, imaging can be carried out using imaging or exposing radiation from an infrared laser (or array of lasers) at a wavelength of at least 750 nm and up to and including about 1400 rim and typically at least 750 rim and up to and including 1250 rim. Imaging can be carried out using imaging radiation at multiple wavelengths at the same time if desired.

The laser used to expose the lithographic printing plate precursor is usually a diode laser, because of the reliability and low maintenance of diode laser systems, but other lasers such as gas or solid-state lasers can also be used. The combination of power, intensity and exposure time for laser imaging would be readily apparent to one skilled in the art. Presently, high performance lasers or laser diodes used in commercially available imagesetters emit infrared radiation at a wavelength of at least 800 rim and up to and including 850 nm or at least 1060 and up to and including 1120 nm.

The imaging apparatus can be configured as a flatbed recorder or as a drum recorder, with the lithographic printing plate precursor mounted to the interior or exterior cylindrical surface of the drum. An example of an useful imaging apparatus is available as models of Kodak® Trendsetter platesetters available from Eastman Kodak Company that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.).

Imaging with infrared radiation can be carried out generally at imaging energies of at least 30 mJ/cm² and up to and including 500 mJ/cm², and typically at least 50 and up to and including 300 mJ/cm².

While laser imaging is desired in the practice of this invention, thermal imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, a Fujitsu Thermal Head FTP-040 MCS001 and TDK Thermal Head F415 HH7-1089).

After imaging, a heating step (pre-heating) might be used to accelerate the formation of a latent image. This heating step can be realized in so called “preheat units” that can be a separate machine or integrated into the processor used to develop the imaged precursor. The most common preheat units use infrared radiation or hot air circulation, or combination thereof, to heat the imaged element. The temperature used for the purpose is at least 70 and up to and including 200° C. However, it can be advantageous to omit the preheating step to simplify the process for making lithographic printing plates.

A pre-rinse step might be carried out in a stand-alone apparatus or by manually rinsing the imaged precursor with water or the pre-rinse step can be carried out in a washing unit that is integrated in a processor used for developing the imaged precursor.

### Development and Printing

After thermal imaging, the imaged precursors are processed (developed) “off-press” using a single aqueous working strength processing solution (developer) that can have a pH of at least 5 and up to and including 12, or typically at least 6 and up to and including 11.5, or even from 8 to 11.5. Processing is carried out for a time sufficient to remove predominantly the non-exposed regions of the imaged imageable layer to reveal the hydrophilic surface of the substrate, but not long enough to remove significant amounts of the exposed regions. The revealed hydrophilic surface repels inks while the exposed regions containing polymerized or crosslinked polymer accept ink. Thus, the non-exposed regions to be removed are “soluble” or “removable” in the developer because they are removed, dissolved, or dispersed within it more readily than the regions that are to remain. The term “soluble” also means “dispersible”.

Development can be accomplished using what is known as “manual” development, “dip” development, or processing with an automatic development apparatus (processor). In the case of “manual” development, development is conducted by rubbing the entire imaged precursor with a sponge or cotton pad sufficiently impregnated with the working strength developer (described below), and optionally followed by rinsing with water. “Dip” development involves dipping the imaged precursor in a tank or tray containing the working strength developer for at least 10 and up to and including 60 seconds under agitation, optionally followed by rinsing with water with or without rubbing with a sponge or cotton pad. The use of automatic development apparatus is well known and generally includes pumping the working strength developer into a developing tank or ejecting it from spray nozzles. The apparatus can also include a suitable rubbing mechanism (for example a brush or roller) and a suitable number of conveyance rollers. Some developing apparatus include laser exposure means and the apparatus is divided into an imaging section and a developing section.

One useful method and apparatus for processing imaged lithographic printing plate precursors is described in copending and commonly assigned U.S. Ser. No. 1/______ (filed by Jarek, Balbinot, and Baumann on even date herewith, and entitled DEVELOPING LITHOGRAPHIC PRINTING PLATE PRECURSORS IN SIMPLE MANNER, Attorney Docket 96523/JLT). In this arrangement, water is added to the working strength developer in a manner to keep the concentration of non-volatile solids relatively constant, but the overall volume of the working strength developer is gradually reduced. However, the processing cycle is increased overall from that expected if no water is added to the working strength developer.

The working strength developers used in the present invention commonly include surfactants (nonionic, anionic, and amphoteric compounds), chelating agents (such as salts of ethylenediaminetetraacetic acid), organic solvents (as described below), wetting agents, anti-foaming agents, antiseptic agents, inorganic salts, and organic amine ink receptivity agents. Conventional alkaline components (such as inorganic metasilicates, organic metasilicates, hydroxides, and bicarbonates) are generally absent from the developers. In particular, the working strength developers are silicate- and metasilicate-free solutions.

The working strength developer includes one or more organic solvents such as the reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol. Benzyl alcohol is particularly useful. The one or more organic solvents are generally present in an amount of at least 7% and up to and including 15%, or at least 10 and up to and including 15%, based on total working strength developer weight particularly if benzyl alcohol is used.

In some instances, the working strength developer can also be used to both develop the imaged precursor by removing predominantly the non-exposed regions and also to provide a protective layer or coating over the entire imaged and developed surface. In this aspect, the developer behaves somewhat like a gum that is capable of protecting (or “gumming”) the lithographic image on the printing plate against contamination or damage (for example, from oxidation, fingerprints, dust, or scratches). The working strength developer thus includes one or more anionic surfactants in an amount of at least 5% and up to and including 45%, or typically at least 7.5% and up to and including 20%, based on total working strength developer weight. Tap water can be used to make up the working strength developer and generally provides at least 50 weight % and up to and including 88 weight %, based on the total working strength developer weight.

Useful anionic surfactants include but are not limited to, surfactants with carboxylic acid, sulfonic acid, or phosphonic acid groups (or salts thereof). Anionic surfactants having sulfonic acid (or salts thereof) groups are particularly useful. For example, anionic surfactants can include aliphates, abietates, hydroxyalkanesulfonates, alkanesulfonates, dialkylsulfosuccinates, alkyldiphenyloxide disulfonates, straight-chain alkylbenzenesulfonates, branched alkylbenzenesulfonates, alkylnaphthalenesulfonates, alkylphenoxypolyoxyethylenepropylsulfonates, salts of polyoxyethylene alkylsulfonophenyl ethers, sodium N-methyl-N-oleyltaurates, monoamide disodium N-alkylsulfosuccinates, petroleum sulfonates, sulfated castor oil, sulfated tallow oil, salts of sulfuric esters of aliphate alkylester, salts of alkylsulfuric esters, sulfuric esters of polyoxyethylene alkylethers, salts of sulfuric esters of aliphatic monoglucerides, salts of sulfuric esters of polyoxyethylenealkylphenylethers, salts of sulfuric esters of polyoxyethylenestyrylphenylethers, salts of alkylphosphoric esters, salts of phosphoric esters of polyoxyethylenealkylethers, salts of phosphoric esters of polyoxyethylenealkylphenylethers, partially saponified compounds of styrene-maleic anhydride copolymers, partially saponified compounds of olefin-maleic anhdyride copolymers, and naphthalenesulfonateformalin condensates. Alkyldiphenyloxide disulfonates (such as sodium dodecyl phenoxy benzene disulfonates), alkylated naphthalene sulfonic acids, sulfonated alkyl diphenyl oxides, and methylene dinaphthalene sulfonic acids) are particularly useful. Particular examples of such surfactants include but are not limited to, sodium dodecylphenoxyoxybenzene disulfonate, the sodium salt of alkylated naphthalenesulfonate, disodium methylene-dinaphthalene disulfonate, sodium dodecylbenzenesulfonate, sulfonated alkyl-diphenyloxide, ammonium or potassium perfluoroalkylsulfonate and sodium dioctylsulfosuccinate.

Particularly useful anionic surfactants is at least one of an alkali alkyl naphthalene sulfonic acid, an alkali salt of alkyl phenyl sulfonic acid, or an alkali diphenyloxide disulfonate that is present in an amount of at least 5 and up to and including 45 weight %, based on total developer weight. Mixtures of these anionic surfactants can be used if desired.

Other useful components of the working strength developers include film-forming water-soluble or hydrophilic polymers such as gum arabic, pullulan, cellulose derivatives (such as hydroxymethyl celluloses, carboxymethylcelluloses, carboxyethylcelluloses, and methyl celluloses), starch derivatives such as (cyclo)dextrins, starch esters, dextrins, carboxymethyl starch, and acetylated starch] poly(vinyl alcohol), poly(vinyl pyrrolidone), polyhydroxy compounds [such as polysaccharides, sugar alcohols such as sorbitol, miso-inosit, homo- and copolymers of (meth)acrylic acid or (meth)acrylamide], copolymers of vinyl methyl ether and maleic anhydride, copolymers of vinyl acetate and maleic anhydride, copolymers of styrene and maleic anhydride, and copolymers having recurring units with carboxy, sulfo, or phospho groups, or salts thereof. Useful hydrophilic polymers include gum arabic, (cyclo)dextrin, a polysaccharide, a sugar alcohol, or a homo- or copolymer having recurring units derived from (meth)acrylic acid.

Following processing, the resulting lithographic printing plate can be used for printing with or without a separate rinsing or gumming step. It is particularly useful that lithographic printing is carried out after development without any intermediate contact with rinsing, gumming, or other treating solutions.

The resulting lithographic printing plate can also be baked in a postbake operation and can be carried out, with or without a blanket or floodwise exposure to UV or visible radiation using known conditions. Alternatively, a blanket UV or visible radiation exposure can be carried out, without a postbake operation.

Printing can be carried out by applying a lithographic printing ink and fountain solution to the printing surface of the imaged and developed precursor. The fountain solution is taken up by the non-imaged regions, that is, the surface of the hydrophilic substrate revealed by the imaging and processing steps, and the ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the lithographic printing plate to the receiving material.

### Substrates

The substrate used to prepare the lithographic printing plate precursors of this invention comprises a support that can be composed of any material that is conventionally used to prepare lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metalized papers), or a lamination of any of these materials (such as a lamination of an aluminum foil onto a polyester film). Metal supports include sheets or foils of aluminum, copper, zinc, titanium, and alloys thereof.

One useful substrate is an aluminum-containing support that can be treated using techniques known in the art, including roughening of some type by physical (mechanical) graining, electrochemical graining, or chemical graining, usually followed by acid anodizing. The aluminum-containing support can be roughened by physical or electrochemical graining and then anodized using phosphoric or sulfuric acid (or a mixture of both phosphoric and sulfuric acids) and conventional procedures. A useful hydrophilic lithographic substrate is an electrochemically grained and sulfuric acid-anodized aluminum-containing substrate that provides a hydrophilic surface for lithographic printing.

Sulfuric acid anodization of the aluminum support generally provides an oxide weight (coverage) on the surface of at least 1.5 and up to and including 5 g/m², and can provide longer press life. Phosphoric acid anodization generally provides an oxide weight on the surface of at least 1 and up to and including 5 g/m².

The aluminum-containing substrate can also be post-treated with, for example, a silicate, dextrin, calcium zirconium fluoride, hexafluorosilicic acid, poly(vinyl phosphonic acid) (PVPA), vinyl phosphonic acid copolymer, poly[(meth)acrylic acid], or an acrylic acid copolymer to increase hydrophilicity. Still further, the aluminum-containing substrate can be treated with a phosphate solution that can further contain an inorganic fluoride (PF). It is particularly useful to post-treat a sulfuric acid-anodized aluminum-containing substrate with poly(vinyl phosphonic acid).

The thickness of the substrate can be varied but should be sufficient to sustain the wear from printing and thin enough to wrap around a printing form. Useful embodiments include a treated aluminum foil having a thickness of at least 100 μm and up to and including 700 μm.

### Negative-Working Lithographic Printing Plate Precursors

The precursors are negative-working, and can be formed by suitable application of a radiation-sensitive composition as described below to a suitable substrate (described above) to form an imageable layer. There is generally only a single imageable layer comprising the radiation-sensitive composition and it is the outermost layer in the element. For the on-press developable lithographic printing plate precursors, no oxygen bather or topcoat is generally present in the lithographic printing plate precursors. However, such a topcoat can be present over the imageable layers designed for off-press development.

Negative-working lithographic printing plate precursors are described for example, in EP Patent Publications 770,494A1 (Vermeersch et al.), 924,570A1 (Fujimaki et al.), 1,063,103A1 (Uesugi), EP 1,182,033A1 (Fujimako et al.), EP 1,342,568A1 (Vermeersch et al.), EP 1,449,650A1 (Goto), and EP 1,614,539A1 (Vermeersch et al.), U.S. Pat. No. 4,511,645 (Koike et al.), U.S. Pat. No. 6,027,857 (Teng), U.S. Pat. No. 6,309,792 (Hauck et al.), U.S. Pat. No. 6,569,603 (Furukawa et al.), U.S. Pat. No. 6,899,994 (Huang et al.), U.S. Pat. No. 7,045,271 (Tao et al.), U.S. Pat. No. 7,049,046 (Tao et al.), U.S. Pat. No. 7,261,998 (Hayashi et al.), U.S. Pat. No. 7,279,255 (Tao et al.), U.S. Pat. No. 7,285,372 (Baumann et al.), U.S. Pat. No. 7,291,438 (Sakurai et al.), U.S. Pat. No. 7,326,521 (Tao et al.), U.S. Pat. No. 7,332,253 (Tao et al.), U.S. Pat. No. 7,442,486 (Baumann et al.), U.S. Pat. No. 7,452,638 (Yu et al.), U.S. Pat. No. 7,524,614 (Tao et al.), U.S. Pat. No. 7,560,221 (Timpe et al.), U.S. Pat. No. 7,574,959 (Baumann et al.), U.S. Pat. No. 7,615,323 (Strehmel et al.), and U.S. Pat. No. 7,672,241 (Munnelly et al.), and U.S. Patent Application Publications 2003/0064318 (Huang et al.), 2004/0265736 (Aoshima et al.), 2005/0266349 (Van Damme et al.), and 2006/0019200 (Vermeersch et al.), all of which are incorporated herein by reference. Other negative-working compositions and elements are described for example in U.S. Pat. No. 6,232,038 (Takasaki), U.S. Pat. No. 6,627,380 (Saito et al.), U.S. Pat. No. 6,514,657 (Sakurai et al.), U.S. Pat. No. 6,808,857 (Miyamoto et al.), and U.S. Patent Publication 2009/0092923 (Hayashi), all of which are incorporated herein by reference.

The radiation-sensitive compositions and imageable layers used in such precursors can generally include one or more particulate polymeric binders that are particulate non-reactive poly(urethane-acrylic) hybrid. By “non-reactive”, we mean that the particulate binders do not contain ethylenically unsaturated or other reactive or crosslinking groups.

The useful polymeric binders are particulate poly(urethane-acrylic) hybrids that are distributed (usually uniformly) throughout the imageable layer. Each of these hybrids has a molecular weight of at least 50,000 and up to and including 500,000 and the particles have an average particle size of at least 10 and up to and including 10,000 nm (typically at least 30 and up to and including 500 nm or at least 30 and up to and including 150 nm). These hybrids can be either “aromatic” or “aliphatic” in nature depending upon the specific reactants used in their manufacture. Blends of particles of two or more poly(urethane-acrylic) hybrids can also be used. Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that can also include commercial surfactants, anti-foaming agents, dispersing agents, anti-corrosive agents, and optionally pigments and water-miscible organic solvents.

These particulate polymeric binders are generally present in an amount of at least 5 and up to and including 80 weight %, or typically at least 10 and up to and including 30 weight %, based on the total solids of the radiation-sensitive composition or imageable layer.

The radiation-sensitive composition can include a secondary polymeric binder that can be homogenous, that is, non-particulate or dissolvable in the coating solvent, or they can exist as discrete particles. Such secondary polymeric binders are generally present in an amount of at least 5 and up to and including 50 weight %, or typically at least 10 and up to and including 30 weight %, based on total imageable layer solids. Useful secondary polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033A1 (Fujimaki et al.) and U.S. Pat. No. 6,309,792 (Hauck et al.), U.S. Pat. No. 6,352,812 (Shimazu et al.), U.S. Pat. No. 6,569,603 (Furukawa et al.), and U.S. Pat. No. 6,893,797 (Munnelly et al.), all of which are incorporated herein by reference. Also useful are the vinyl carbazole polymers described in U.S. Pat. No. 7,175,949 (Tao et al.), and the polymers having pendant vinyl or ethylenically unsaturated polymerizable groups as described in U.S. Pat. No. 7,279,255 (Tao et al.), both patents being incorporated herein by reference. Useful random copolymers are derived from polyethylene glycol methacrylate, acrylonitrile, and styrene monomers in random fashion, dissolved random copolymers derived from carboxyphenyl methacrylamide, acrylonitrile, methacrylamide, and N-phenyl maleimide, random copolymers derived from polyethylene glycol methacrylate, acrylonitrile, vinyl carbazole, styrene, and methacrylic acid, random copolymers derived from N-phenyl maleimide, methacrylamide, and methacrylic acid, random copolymers derived from urethane-acrylic intermediate A (the reaction product of p-toluene sulfonyl isocyanate and hydroxyl ethyl methacrylate), acrylonitrile, and N-phenyl maleimide, and random copolymers derived from N-methoxymethyl methacrylamide, methacrylic acid, acrylonitrile, and n-phenylmaleimide. By “random” copolymers, we mean the conventional use of the term, that is, the structural units in the polymer backbone that are derived from the monomers are arranged in random order as opposed to being block copolymers, although two or more of the same structural units can be in a chain incidentally.

Other useful secondary polymeric binders are included in the following non-exhaustive list:

I. Polymers formed by random polymerization of a combination or mixture of (a) (meth)acrylonitrile, (b) poly(alkylene oxide) esters of (meth)acrylic acid, and optionally (c) (meth)acrylic acid, (meth)acrylate esters, styrene and its derivatives, and (meth)acrylamide as described for example in U.S. Pat. No. 7,326,521 (Tao et al.) that is incorporated herein by reference. Some particularly useful polymeric binders in this class are derived from one or more (meth)acrylic acids, (meth)acrylate esters, styrene and its derivatives, vinyl carbazoles, and poly(alkylene oxide) (meth)acrylates in random fashion.

II. Polymers having pendant allyl ester groups as described in U.S. Pat. No. 7,332,253 (Tao et al.) that is incorporated herein by reference. Such polymers can also include pendant cyano groups or have recurring units derived from a variety of other monomers as described in Col. 8, line 31 to Col. 10, line 3 of the noted patent.

III. Polymers having all carbon backbones wherein at least 40 and up to 100 mol % (and typically from about 40 to about 50 mol %) of the carbon atoms forming the all carbon backbones are tertiary carbon atoms, and the remaining carbon atoms in the all carbon backbone being non-tertiary carbon atoms. By “tertiary carbon”, we refer to a carbon atom in the all carbon backbone that has three valences filled with radicals or atoms other than a hydrogen atom (which fills the fourth valence). By “non-tertiary carbon”, we mean a carbon atom in the all carbon backbone that is a secondary carbon (having two valences filled with hydrogen atoms) or a quaternary carbon (having no hydrogen atoms attached). Typically, most of the non-tertiary carbon atoms are secondary carbon atoms. One way to represent a tertiary carbon atom in the all carbon backbone is with the following Structure (T-CARBON):

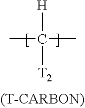

wherein T₂ is a group other than hydrogen provided that T₂ does not include an ethylenically unsaturated free radically reactive group (such as a —C═C— group). In many embodiments, T₂ is a pendant group selected from N-carbazole, aryl (defined similarly as for Ar below), halo, cyano, —C(═O)R, —C(=O)Ar, —C(═O)OR, —C(═O)OAr, —C(═O)NHR, and —C(═O)NHAr pendant groups, wherein R is hydrogen or an alkyl, cycloalkyl, halo, alkoxy, acyl, or acyloxy group, and Ar is an aryl group other than a styryl group. The quaternary carbon atoms present in the all carbon backbone of the polymeric binder can also have the same or different pendant groups filling two of the valences. For example, one or both valences can be filled with the same or different alkyl groups as defined above for R, or one valence can be filled with an alkyl group and another valence can be filled with a N-carbazole, aryl other than a styryl group, halo, cyano, —C(═O)R, —C(═O)Ar, —C(═O)OR, —C(═O)OAr, —C(═O)NHR, or —C(═O)NHAr pendant group, wherein R and Ar are as defined above. The pendant groups attached to the tertiary and quaternary carbons in the all carbon backbone can be the same or different and typically, they are different. It should also be understood that the pendant groups attached to the various tertiary carbon atoms can be the same throughout the polymeric molecule, or they can be different. For example, the tertiary carbon atoms can be derived in random fashion from the same or different ethylenically unsaturated polymerizable monomers. Moreover, the quaternary carbon atoms throughout the polymeric molecule can have the same or different pendant groups.

Representative recurring units comprising tertiary carbon atoms can be derived from one or more ethylenically unsaturated polymerizable monomers selected from vinyl carbazole, styrene and derivatives thereof (other than divinylbenzene and similar monomers that provide pendant carbon-carbon polymerizable groups), acrylic acid, acrylonitrile, acrylamides, acrylates, and methyl vinyl ketone. Similarly, representative recurring units with secondary or quaternary carbon atoms can be derived from one or more ethylenically unsaturated polymerizable monomers selected from methacrylic acid, methacrylates, methacrylamides, and a-methylstyrene.

IV. Polymeric binders that have one or more pendant ethylenically unsaturated polymerizable groups (reactive vinyl groups) attached to the polymer backbone. Such reactive groups are capable of undergoing polymerizable or crosslinking in the presence of free radicals. The pendant groups can be directly attached to the polymer backbone with a carbon-carbon direct bond, or through a linking group (“X”) that is not particularly limited. The reactive vinyl groups can be substituted with at least one halogen atom, carboxy group, nitro group, cyano group, amide group, or alkyl, aryl, alkoxy, or aryloxy group, and particularly one or more alkyl groups. In some embodiments, the reactive vinyl group is attached to the polymer backbone through a phenylene group as described, for example, in U.S. Pat. No. 6,569,603 (Furukawa et al.) that is incorporated herein by reference. Other useful polymeric binders have vinyl groups in pendant groups that are described, for example in EP 1,182,033A1 (Fujimaki et al.) and U.S. Pat. No. 4,874,686 (Urabe et al.), U.S. Pat. No. 7,729,255 (Tao et al.), 6,916,595 (Fujimaki et al.), and U.S. Pat. No. 7,041,416 (Wakata et al.) that are incorporated by reference, especially with respect to the general formulae (1) through (3) noted in EP 1,182,033A1.

V. Polymeric binders can have pendant 1H-tetrazole groups as described in U.S. Patent Application Publication 2009-0142695 (Baumann et al.) that is incorporated herein by reference.

The radiation-sensitive composition (and imageable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used. Oligomers or prepolymers, such as urethane acrylates and methacrylates, epoxide acrylates and methacrylates, polyester acrylates and methacrylates, polyether acrylates and methacrylates, and unsaturated polyester resins can be used. In some embodiments, the free radically polymerizable component comprises carboxyl groups.

Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (Fujimaki et al.), beginning with paragraph [0170], and in U.S. Pat. No. 6,309,792 (Hauck et al.), U.S. Pat. No. 6,569,603 (Furukawa), and U.S. Pat. No. 6,893,797 (Munnelly et al.). Other useful free radically polymerizable components include those described in U.S. Patent Application Publication 2009/0142695 (Baumann et al.), which radically polymerizable components include 1H-tetrazole groups.

In addition to, or in place of the free radically polymerizable components described above, the radiation-sensitive composition can include polymeric materials that include side chains attached to the backbone, which side chains include one or more free radically polymerizable groups (such as ethylenically unsaturated groups) that can be polymerized (crosslinked) in response to free radicals produced by the initiator composition (described below). There can be at least two of these side chains per molecule. The free radically polymerizable groups (or ethylenically unsaturated groups) can be part of aliphatic or aromatic acrylate side chains attached to the polymeric backbone. Generally, there are at least 2 and up to and including 20 such groups per molecule.

Such free radically polymerizable polymers can also comprise hydrophilic groups including but not limited to, carboxy, sulfo, or phospho groups, either attached directly to the backbone or attached as part of side chains other than the free radically polymerizable side chains.

This radiation-sensitive composition also includes an initiator composition that includes one or more initiators that are capable of generating free radicals sufficient to initiate polymerization of all the various free radically polymerizable components upon exposure of the composition to imaging infrared radiation. The initiator composition is responsive, for example, to electromagnetic radiation in the infrared spectral regions, corresponding to the broad spectral range of at least 700 nm and up to and including 1400 nm, and typically radiation of at least 700 nm and up to and including 1250 nm.

More typically, the initiator composition includes one or more an electron acceptors and one or more co-initiators that are capable of donating electrons, hydrogen atoms, or a hydrocarbon radical.

In general, suitable initiator compositions for IR-radiation sensitive compositions comprise initiators that include but are not limited to, aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, trihalogenomethyl-arylsulfones, benzoin ethers and esters, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), trihalomethyl substituted triazines, boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts).

Useful initiator compositions for IR radiation sensitive compositions include onium compounds including ammonium, sulfonium, iodonium, and phosphonium compounds. Useful iodonium cations are well known in the art including but not limited to, U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, a useful iodonium cation includes a positively charged iodonium, (4-methylphenyl)[4-(2-methylpropyl)phenyl]-moiety and a suitable negatively charged counterion.

Thus, the iodonium cations can be supplied as part of one or more iodonium salts, and the iodonium cations can be supplied as iodonium borates also containing suitable boron-containing anions. For example, the iodonium cations and the boron-containing anions can be supplied as part of substituted or unsubstituted diaryliodonium salts that are combinations of Structures (I) and (II) described in Cols. 6-8 of U.S. Pat. No. 7,524,614 (Tao et al.) that is incorporated herein by reference.

Useful IR radiation-sensitive initiator compositions can comprise one or more diaryliodonium borate compounds. Representative iodonium borate compounds useful in this invention include but are not limited to, 4-octyloxyphenyl phenyliodonium tetraphenylborate, [4-[(2-hydroxytetradecyl)-oxylphenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexyl-phenyliodonium n-butyltriphenylborate, 4-cyclohexylphenyl-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]borate, 4-methoxyphenyl-4′-cyclohexyl-phenyliodonium tetrakis(penta-fluorophenyl)borate, 4-methylphenyl-4% dodecylphenyliodonium tetrakis(4-fluorophenyl)borate, bis(dodecylphenyl)-iodonium tetrakis(pentafluorophenyl)-borate, and bis(4-t-butylphenyl)iodonium tetrakis(1-imidazolyl)borate. Useful compounds include bis(4-t-butylphenyl)-iodonium tetraphenylborate, 4-methylphenyl-4′-hexylphenyliodonium tetraphenylborate, 2-methyl-4-t-butylphenyl-4′-methylphenyliodonium tetraphenylborate, and 4-methylphenyl-4′-cyclohexylphenyliodonium tetraphenylborate. Mixtures of two or more of these compounds can also be used in the initiator composition.

The imageable layers comprise a radiation-sensitive imaging composition that includes one or more infrared radiation absorbing compounds, such as first and second infrared radiation absorbing compounds. If only a single infrared radiation absorbing compound is present, it can be any of the compounds described below. The total amount of one or more infrared radiation absorbing compounds is at least 2 and up to and including 30 weight %, or typically at least 5 and up to and including 20 weight %, based on the imageable layer total solids.

Thus, the infrared radiation (IR) absorbing compounds are sensitive to both infrared radiation (typically of at least 700 and up to and including 1400 nm) and visible radiation (typically of at least 450 and up to and including 700 nm). Some useful compounds have a tetraaryl pentadiene chromophore. Such chromophore generally includes a pentadiene linking group having 5 carbon atoms in the chain, to which are attached two substituted or unsubstituted aryl groups at each end of the linking group. These aryl groups can be substituted with the same or different tertiary amine groups. The pentadiene linking group can also be substituted with one or more substituents in place of the hydrogen atoms, or two or more hydrogen atoms can be replaced with atoms to form a ring in the linking group as long as there are alternative carbon-carbon single bonds and carbon-carbon double bonds in the chain. For example, useful first infrared radiation absorbing compounds can be represented by the following Structure (DYE-I)

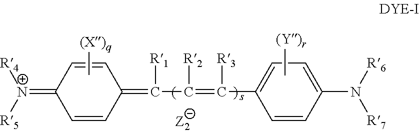

wherein R₁′, R₂′, and R₃′ each independently represents hydrogen, or a halo, cyano, alkoxy, acyloxy, acyloxy, carbamoyl, acyl, acylamido, alkylamino, arylamino, alkyl, aryl, or heteroaryl group, or any two of R₁′, R₂′, and R₃′ groups can be joined together or with an adjacent aromatic ring to complete a 5- to 7-membered carbocylic or heterocyclic ring,

R₄′, R₅′, R₆′, and R₇′ each independently represents hydrogen, an alkyl group having 1 to 8 carbon atoms, a cycloalkyl group having 4 to 6 carbon atoms in the ring, an aryl group having 6 to 10 carbon atoms in the ring, or a heteroaryl group having 5 to 10 carbon and heteroatoms in the ring, or R₄′ and R₅′ or R₆′ and R₇′ can be joined together to form a 5- to 9-membered heterocyclic ring, or R₄′, R₅′, R₆′, or R₇′ can be joined to a carbon atom of an adjacent aromatic ring at a position ortho to the position of attachment of the anilino nitrogen to form, along with the nitrogen to which they are attached, a 5- or 6-membered heterocyclic ring,

s is 2,

Z₂ is a monovalent anion,

X″ and Y″ are independently R₁′ or the atoms necessary to complete a 5- to 7-membered fused carbocyclic or heterocyclic ring, and

q and r are independently integers of from 1 to 4.

In Structure (DYE-I), Z₂⁻ is a suitable counterion that can be derived from a strong acid, and include such anions as ClO₄⁻, BF₄⁻, CF₃SO₃⁻, PF₆⁻, AsF₆⁻, SbF₆⁻, and perfluoroethylcyclohexylsulfonate. Other cations include boron-containing anions as described above (borates), methylbenzenesulfonic acid, benzenesulfonic acid, methanesulfonic acid, p-hydroxybenzenesulfonic acid, p-chlorobenzenesulfonic acid, tosylate, and halides. Particularly useful counterions are alkyltriphenyl borate anions.

Other useful IR absorbing compounds include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are described in U.S. Pat. No. 5,208,135 (Patel et al.), U.S. Pat. No. 6,153,356 (Urano et al.), U.S. Pat. No. 6,264,920 (Achilefu et al.), U.S. Pat. No. 6,309,792 (Hauck et al.), U.S. Pat. No. 6,569,603 (noted above), U.S. Pat. No. 6,787,281 (Tao et al.), U.S. Pat. No. 7,018,775 (Tao), U.S. Pat. No. 7,135,271 (Kawaushi et al.), and EP 1,182,033A2 (noted above), and paragraph [0026] of WO 2004/101280 (Munnelly et al.), all incorporated herein by reference for these compounds.

IR-absorbing dyes having IR dye chromophores bonded to polymers can be used as well. Moreover, IR dye cations can be used, that is, the cation is the IR absorbing portion of the dye salt that ionically interacts with a polymer comprising carboxy, sulfo, phospho, or phosphono groups in the side chains.

Suitable dyes can be formed using conventional methods and starting materials or obtained from various commercial sources including American Dye Source (Baie D′Urfe, Quebec, Canada) and FEW Chemicals (Germany). Other useful dyes for near infrared diode laser beams are described in U.S. Pat. No. 4,973,572 (DeBoer).

Still other useful IR-radiation sensitive compositions are described, for example, in U.S. Pat. No. 7,452,638 (Yu et al.), and U.S. Patent Application Publications 2008/0254387 (Yu et al.), 2008/0311520 (Yu et al.), 2009/0263746 (Ray et al.), and 2010/0021844 (Yu et al.), all incorporated herein by reference.

The imageable layer can also include a poly(alkylene glycol) or an ether or ester thereof that has a molecular weight of at least 200 and up to and including 4000. Useful compounds of this type include, but are not limited to, one or more of polyethylene glycol, polypropylene glycol, polyethylene glycol methyl ether, polyethylene glycol dimethyl ether, polyethylene glycol monoethyl ether, polyethylene glycol diacrylate, ethoxylated bisphenol A di(meth)acrylate, and polyethylene glycol mono methacrylate.

The imageable layer can further include a poly(vinyl alcohol), a poly(vinyl pyrrolidone), poly(vinyl imidazole), or polyester in an amount of up to and including 20 weight % based on the total dry weight of the imageable layer.

Additional additives to the imageable layer include color developers or acidic compounds. As color developers, we mean to include monomeric phenolic compounds, organic acids or metal salts thereof, oxybenzoic acid esters, acid clays, and other compounds described for example in U.S. Patent Application Publication 2005/0170282 (Irmo et al.). The imageable layer can also include a variety of optional compounds including but not limited to, dispersing agents, humectants, biocides, plasticizers, surfactants for coatability or other properties, viscosity builders, pH adjusters, drying agents, defoamers, preservatives, antioxidants, development aids, rheology modifiers or combinations thereof, or any other addenda commonly used in the lithographic art, in conventional amounts.

The radiation-sensitive composition and imageable layer optionally includes a phosphate (meth)acrylate having a molecular weight generally greater than 250 as described in U.S. Pat. No. 7,429,445 (Munnelly et al.) that is incorporated herein by reference. By “phosphate (meth)acrylate” we also mean “phosphate methacrylates” and other derivatives having substituents on the vinyl group in the acrylate moiety.

The IR radiation-sensitive composition can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying it onto a suitable support (such as an on-press printing cylinder). Typically, the radiation-sensitive composition is applied and dried to form an imageable layer.

In most embodiments, the outermost layer can be a water-soluble or water-dispersible overcoat (also sometimes known as an “oxygen impermeable topcoat” or “oxygen barrier layer”) disposed over the imageable layer. Such overcoat layers can comprise one or more water-soluble poly(vinyl alcohol)s having a saponification degree of at least 90% and generally have a dry coating weight of at least 0.1 and up to and including 2 g/m² in which the water-soluble poly(vinyl alcohol)s comprise at least 60% and up to and including 99% of the dry overcoat layer weight. Some topcoats have a dry coverage of 0.5 g/m² or less.

The overcoat can further comprise a second water-soluble polymer that is not a poly(vinyl alcohol) in an amount of from about 2 to about 38 weight %, and such second water-soluble polymer can be a poly(vinyl pyrrolidone), poly(ethyleneimine), poly(vinyl imidazole), poly(vinyl caprolactone), or a random copolymer derived from two or more of vinyl pyrrolidone, ethyleneimine, vinyl caprolactone, and vinyl imidazole, and vinyl acetamide.

Alternatively, the overcoat can be formed predominantly using one or more of polymeric binders such as poly(vinyl pyrrolidone), poly(ethyleneimine), poly(vinyl imidazole), and random copolymers from two or more of vinyl pyrrolidone, ethyleneimine and vinyl imidazole, and mixtures of such polymers. The formulations can also include cationic, anionic, and non-ionic wetting agents or surfactants, flow improvers or thickeners, antifoamants, colorants, particles such as aluminum oxide and silicon dioxide, and biocides. Details about such addenda are provided in WO 99/06890 (Pappas et al.) that is incorporated by reference.

Illustrative of such manufacturing methods is mixing the various components needed for a specific imaging chemistry in a suitable organic solvent or mixtures thereof [such as methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], applying the resulting solution to a substrate, and removing the solvent(s) by evaporation under suitable drying conditions. Some representative coating solvents and imageable layer formulations are described for the Invention Examples below. After proper drying, the coating weight of the imageable layer is generally at least 0.1 and up to and including 5 g/m² or at least 0.5 and up to and including 3.5 g/m².

Layers can also be present under the imageable layer to enhance developability or to act as a thermal insulating layer.

Once the various layers have been applied and dried on the substrate, the negative-working imageable elements can be enclosed in water-impermeable material that substantially inhibits the transfer of moisture to and from the element and “heat conditioned” as described in U.S. Pat. No. 7,175,969 (Ray et al.) that is incorporated herein by reference.

The lithographic printing plate precursors can be stored and transported as stacks of precursors within suitable packaging and containers known in the art.

The present invention provides at least the following embodiments and combinations thereof, but other combinations of features are considered to be within the present invention as a skilled artisan would appreciate from the teaching of this disclosure:

1. A method of providing a lithographic printing plate comprising:

A) imagewise exposing a negative-working lithographic printing plate precursor having a hydrophilic substrate and an imageable layer disposed on the hydrophilic substrate, to provide exposed and non-exposed regions in the

imageable layer of the imagewise exposed precursor, the imageable layer comprising a free radically polymerizable component, an initiator composition that provides free radicals upon imagewise exposure, a radiation absorbing compound, and a particulate non-reactive poly(urethane-acrylic) hybrid, and

B) with or without a preheat step, processing the imagewise exposed precursor with a working strength developer comprising one or more organic solvents in a total amount of at least 7 weight % and an anionic surfactant in an amount of at least 5 weight %, to remove the non-exposed regions in the imageable layer.

2. The method of embodiment 1 wherein the one or more organic solvents are present in the working strength developer in a total amount of at least 7 and up to and including 15 weight %.

3. The method of any of embodiment 1 or 2 wherein the one or more solvents are selected from the group consisting of benzyl alcohol, a reaction product of phenol with ethylene oxide or propylene oxide, and an ester of ethylene glycol or propylene glycol with an acid having 6 or less carbon atoms.

4. The method of any of embodiments 1 to 3 wherein the one or more organic solvents includes benzyl alcohol that is present in an amount of at least 10 and up to and including 15 weight %.

5. The method of any of embodiments 1 to 4 wherein the anionic surfactant is at least one of an alkali alkyl naphthalene sulfonic acid, an alkali salt of alkyl phenyl sulfonic acid, or an alkali diphenyloxide disulfonate that is present in an amount of at least 5 and up to and including 45 weight %.

6. The method of any of embodiments 1 to 5 wherein the working strength developer is silicate- and metasilicate-free.

7. The method of any of embodiments 1 to 6 wherein the poly(urethane-acrylic) hybrid is present in the imageable layer in an amount of at least 5 and up to and including 80 weight %, based on total imageable layer solids.

8. The method of any of embodiments 1 to 7 wherein the lithographic printing plate precursor further comprises a topcoat disposed on the imageable layer at a coverage of 0.5 g/m² or less.

9. The method of any of embodiments 1 to 8 wherein the lithographic printing plate precursor is sensitive to infrared radiation and the imagewise exposing is carried out at the wavelength of at least 700 nm and up to and including 1400 nm.

10. The method of any of embodiments 1 to 9 wherein the developer further comprises any one or more of a nonionic surfactant, chelating agent, wetting agent, anti-foaming agent, antiseptic agent, inorganic salt, and organic amine ink receptivity agent.

11. The method of any of embodiments I to 10 wherein the hydrophilic substrate is a sulfuric acid-anodized aluminum-containing support having a poly(vinyl phosphonic acid) post-treatment.

12. The method of any of embodiments 1 to 11 wherein the imageable layer further comprises a secondary polymeric binder that is non-particulate in nature, and is present in an amount of at least 5 and up to and including 50 weight %, based on total imageable layer solids.

13. The method of embodiment 12 wherein the secondary polymeric binder has pendant ethylenically unsaturated polymerizable groups.

The following Examples are provided to illustrate the practice of this invention and are not meant to be limiting in any manner. In these examples, the following components and materials were used in the examples, and are commercially available from various sources if no specific source is noted:

BLO represents y-butyrolactone.

Byk® 307 is a polyethoxylated dimethyl polysiloxane that was obtained from Byk Chemie.

CD9053 adhesion promoter was obtained from Sartomer.

Hybridur® 580 is a urethane-acrylic hybrid polymer dispersion was obtained from Air Products and Chemicals.

Dowanol® PM is propylene glycol methyl ether (Dow Chemical).

EDTA is ethylene diaminetetraacetic acid.

Ethylan HB4 is a nonionic surfactant that was obtained from Akzo Nobel.

IB05 represents bis(4-t-butylphenyl)-iodonium tetraphenylborate.

Lugalvan® BNO12 is a non-ionic surfactant that was obtained from BASF.

Lutensor TO10 ethoxylated C13 alcohol was obtained from BASF.

Mazol® PGO-31K is a triglycerol monooleate that was obtained from BASF.

MEK represents methyl ethyl ketone.

Naxan® ABL is an anionic surfactant available from Nease Co.

Pig951 is a Cu-phthalocyanine pigment dispersion.

Pluronic® PE6400 is a non-ionic surfactant that was obtained from BASF.

Polymer 1 is a 20/40/20/20 weight ratio copolymer formed by random polymerization of methacrylic acid, ally! methacrylic acid ester, benzyl methacrylic acid ester, and isopropyl acrylamide and had an acid number of 87.

Polymer 2 is a 28/20/40/12 weight ratio copolymer formed by random polymerization of benzyl methacrylic acid ester, vinyl carbazole, acrylonitrile, and methacrylic acid.

PVA403 is a poly(vinyl alcohol) that was obtained from Kuraray.

S0507 is an IR dye that was obtained from FEW Chemicals GmbH.

SR399 is dipentaerythrithol pentaacrylate that was obtained from Sartomer.

Surfynol® 440 is a nonionic surfactant that was obtained from Air Products and Chemicals.

956 Developer is a commercial developer (Eastman Kodak Company) containing 4.58 weight % of phenoxyethanol at its working strength.

955 Developer is a commercial developer (Eastman Kodak Company) containing 3.7 weight % of benzyl alcohol at its working strength.

980 Developer is a commercial developer (Eastman Kodak Company) containing 3.82 weight % of phenoxyethanol at its working strength.

Working strength Developer 1 contained 10 g of benzyl alcohol, 30 g of Naxan® ABL, 0.04 g of Mazol® PGO-31K, 0.3 g of EDTA, 2 g of tetrapotassium pyrophosphate, 0.9 g of sodium metabisulfate, and 56.76 g of water.

Working strength Developer 2 contained 5 g of phenoxyethanol, 20 g of Naxan® ABL, 0.04 g of Mazol® PGO-31K, 0.3 g of EDTA, 2 g of tetrapotassium pyrophosphate, 0.9 g of sodium metabisulfate, and 71.76 g of water.

Working strength Developer 3 contained 10 g of benzyl alcohol, 30 g of Mazol® PGO-31K, 0.3 g of EDTA, 2 g of tetrapotassium pyrophosphate, 0.9 g of sodium metabisulfate, and 86.76 g of water.

Working strength Developer 4 contained 10 g of benzyl alcohol, 2.5 g of Ethylan HB4, 2.5 g of Pluronic® PE6400, 0.3 g of EDTA, 2 g of tetrapotassium pyrophosphate, 0.9 g of sodium metabisulfate, and 86.76 g of water.

Working strength Developer 5 contained 10 g of phenoxyethanol, 15 g of Naxan® ABL, 0.3 g of EDTA, 2 g of tetrapotassium pyrophosphate, 2.5 g of Ethylan HB4, and 70.2 g of water.

Working strength Developer 6 contained 5 g of phenoxyethanol, 4.5 g of Naxan® ABL, 0.3 g of EDTA, 2 g of tetrapotassium pyrophosphate, and 88.2 g of water.

### Lithographic Printing Plate Precursor 1:

An imageable layer formulation was prepared by dissolving or dispersing 2.45 g of Hybridur® 580, 2.94 g of SR399, 0.12 g of CD9053, 1.68 g of Pig051, 0.22 g of IB05, 0.06 g of 50507, and 0.12 g of Byk® 307 in 2.03 g of BLO, 7.89 g of MEK, and 7.20 g of Dowanol® PM.

This imageable layer formulation was applied to an electrochemically grained and anodized aluminium substrate that has been post-treated with poly(vinyl phosphoric acid) to provide a dry coating weight of about 1.2 g/m². On the dried imageable layer, a top coat layer was applied from a formulation comprising 0.978 g of PVA403, 0.2 g of Lutensol® TO10, 0.02 g of Surfynol® 440, and 50 g of water to provide a dry coating weight of 0.5 g.

The resulting negative-working lithographic printing plate precursors were placed on a Kodak® Trendsetter 800 II Quantum platesetter (830 nm) using a gray scale wedge with defined tonal values for evaluating the quality of the copies and exposed at 80 mJ/cm² using an 830 nm IR laser. The imaged precursors were then developed as shown in TABLE I at 23° C. Developability results are below in TABLE I.

### Lithographic Printing Plate Precursor 2:

An imageable layer formulation was prepared by dissolving or dispersing 0.73 g of Hybridur® 580, 0.44 g of Polymer 2, 2.94 g of SR399, 0.12 g of CD9053, 1.68 g of Pig051, 0.22 g of 1B05, 0.06 g of S0507, and 0.12 g of Byk® 307 in 2.03 g of BLO, 7.89 g of MEK, 7.20 g of Dowanol® PM, and 0.25 g of water.

This imageable layer formulation was applied to an electrochemically grained and anodized aluminium substrate that has been post-treated with poly(vinyl phosphoric acid) to provide a dry coating weight of about 1.2 g/m². On this dried imageable layer, a top coat layer was applied from a formulation comprising 0.978 g of PVA403, 0.2 g of Lutensol® TO10, 0.02 g of Surfynol® 440, and 50 g of water to provide a dry coating weight of 0.5 g.

The resulting negative-working lithographic printing plate precursors were imaged as described in Invention Example 1, and then developed at 23° C. as shown below in TABLE I.

### Lithographic Printing Plate Precursor 3:

An imageable layer formulation was prepared by dissolving or dispersing 0.73 g of Hybridur® 580, 0.44 g of Polymer 1, 2.94 g of SR399, 0.12 g of CD9053, 1.68 g of Pig051, 0.22 g of IB05, 0.06 g of S0507, and 0.12 g of Byk® 307 in 2.03 g of BLO, 7.89 g of MEK, 7.20 g of Dowanol® PM, and 0.25 g of water.

This imageable layer formulation was applied to an electrochemically grained and anodized aluminium substrate that has been post-treated with poly(vinyl phosphoric acid) to provide a dry coating weight of about 1.2 g/m². On this dried imageable layer, a top coat layer was applied from a formulation comprising 0.978 g of PVA403, 0.2 g of Lutensol® TO10, 0.02 g of Surfynol® 440, and 50 g of water to provide a dry coating weight of 0.5 g.

The resulting negative-working lithographic printing plate precursors were imaged as described in Invention Example 1, and then developed at 23° C. as shown below in TABLE I.

### Lithographic Printing Plate Precursor 4:

An imageable layer formulation was prepared by dissolving or dispersing 0.73 g of Hybridur® 580, 0.44 g of Polymer 1, 2.94 g of SR399, 0.12 g of CD9053, 1.68 g of Pig051, 0.22 g of IB05, 0.06 g of S0507, and 0.12 g of Byk® 307 in 2.03 g of BLO, 7.89 g of MEK, 7.20 g of Dowanol® PM, and 0.25 g of water.

This imageable layer formulation was applied to an electrochemically grained and anodized aluminium substrate that has been post-treated with poly(vinyl phosphoric acid) to provide a dry coating weight of about 1.2 g/m². No topcoat was applied.

The resulting negative-working lithographic printing plate precursors were imaged as described in Invention Example 1, and then developed at 23° C. as shown below in TABLE I.

### Lithographic Printing Plate Precursor 5:

An imageable layer formulation was prepared by dissolving or dispersing 0.98 g of Polymer 2, 2.94 g of SR399, 0.12 g of CD9053, 1.68 g of Pig051, 0.22 g of IB05, 0.06 g of S0507, and 0.12 g of Byk® 307 in 1.90 g of BLO, 7.76 g of MEK, 7.07 g of Dowanol® PM, and 1.06 g of water.

The imageable layer formulation was applied to an electrochemically grained and anodized aluminium substrate that has been post-treated with poly(vinyl phosphoric acid) to provide a dry coating weight of about 1.2 g/m². On this dried imageable layer, a top coat layer was applied from a formulation comprising 0.978 g of PVA403, 0.2 g of Lutensol® TO10, 0.02 g of Surfynol® 440, and 50 g of water to provide a dry coating weight of 0.5 g.

The resulting negative-working lithographic printing plate precursors were imaged as described in Invention Example 1, and then developed at 23° C. as shown in TABLE I.

Shelf life of these precursors was assessed after 10 days of aging in a wrapped stack of precursors in an oven at 40° C./80% relative humidity. Shelf life results are also shown below in TABLE I.

TABLE I

| Working | | | | | |
|---|---|---|---|---|---|
| Strength | Ele- | Ele- | Ele- | Ele- | Ele- |
| Developer | ment 1 | ment 2 | ment 3 | ment 4 | ment 5 |
| 1 | Good | Good | Good | Good | Bad |
| 2 | Good | Good | Good | Good | Bad |
| 956 | Peeling* | Peeling | Slight | Slight | Good |
| Developer | | | peeling | peeling | |
| 955 | Peeling | Peeling | Peeling | Peeling | Good |
| Developer | | | | | |
| 980 | Peeling | Peeling | Peeling | Peeling | Good |
| Developer | | | | | |
| 3** | Not tested | Not tested | Not tested | Not tested | Bad |
| 4** | Not tested | Not tested | Not tested | Not tested | Bad |
| 5 | Good | Good | Good | Good | Bad |
| 6 | Peeling | Peeling | Peeling | Peeling | Bad |
| Shelf Life | Good | Good | Good | Good | Wood |
| | | | | | grain*** |

*“Peeling” refers to coating in non-image regions that are not dissolved in the developer but which peel off the substrate as flakes.
**Phase separate was observed.
***Wood grain is a visual appearance of wood grain like pattern on the lithographic printing plate precursor.

TABLE II

| Working Strength | |
|---|---|
| Developer | Cleanliness of processing machine* |
| 1 | Very clean |
| 2 | Slight precipitation of coating residue and coating |
| | residue deposition on the coating rollers |
| 956 Developer | Heavy sludge formation |
| 955 Developer | Heavy sludge formation |
| 980 Developer | Heavy sludge formation |
| 5 | Clean |
| 6 | Heavy sludge formation |

*Coating formulation of Lithographic Printing Plate Precursor 1 was used for evaluation of cleanliness of processing machine.

The results shown in TABLES I and II above show that use of the working strength developers according to the present invention provide important improvements in shelf life, developability, and reduced sludge in the processor.

The invention has been described in detail with particular reference to certain preferred embodiments thereof, but it will be understood that variations and modifications can be effected within the spirit and scope of the invention.

1. A method of providing a lithographic printing plate comprising:
A) imagewise exposing a negative-working lithographic printing plate precursor having a hydrophilic substrate and an imageable layer disposed on the hydrophilic substrate, to provide exposed and non-exposed regions in the imageable layer of the imagewise exposed precursor,
the imageable layer comprising a free radically polymerizable component, an initiator composition that provides free radicals upon imagewise exposure, a radiation absorbing compound, and a particulate non-reactive poly(urethane-acrylic) hybrid, and
B) with or without a preheat step, processing the imagewise exposed precursor with a working strength developer comprising one or more organic solvents in a total amount of at least 7 weight % and an anionic surfactant in an amount of at least 5 weight %, to remove the non-exposed regions in the imageable layer.

2. The method of claim 1 wherein one or more organic solvents are present in the working strength developer in a total amount of at least 7 and up to and including 15 weight %.

3. The method of claim 1 wherein the one or more organic solvents are selected from the group consisting of benzyl alcohol, a reaction product of phenol with ethylene oxide or propylene oxide, and an ester of ethylene glycol or propylene glycol with an acid having 6 or less carbon atoms.

4. The method of claim 1 wherein the one or more organic solvents include benzyl alcohol that is present in an amount of at least 10 and up to and including 15 weight %.

5. The method of claim 1 wherein the anionic surfactant is at least one of an alkali alkyl naphthalene sulfonic acid, an alkali salt of alkyl phenyl sulfonic acid, or an alkali diphenyloxide disulfonate that is present in an amount of at least 5 and up to and including 45 weight %.

6. The method of claim 1 wherein the working strength developer is silicate- and metasilicate-free.

7. The method of claim 1 wherein the poly(urethane-acrylic) hybrid is present in the imageable layer in an amount of at least 5 and up to and including 80 weight %, based on total imageable layer solids.

8. The method of claim 1 wherein the lithographic printing plate precursor further comprises a topcoat disposed on the imageable layer at a coverage of 0.5 g/m² or less.

9. The method of claim 1 wherein the lithographic printing plate precursor is sensitive to infrared radiation and the imagewise exposing is carried out at the wavelength of at least 700 nm and up to and including 1400 nm.

10. The method of claim 1 wherein the working strength developer further comprises any one or more of a nonionic surfactant, chelating agent, wetting agent, anti-foaming agent, antiseptic agent, inorganic salt, and organic amine ink receptivity agent.

11. The method of claim 1 wherein the hydrophilic substrate is a sulfuric acid-anodized aluminum-containing support having a poly(vinyl phosphonic acid) post-treatment.

12. The method of claim 1 wherein the imageable layer further comprises a secondary polymeric binder that is non-particulate in nature, and is present in an amount of at least 5 and up to and including 50 weight %, based on total imageable layer solids.

13. The method of claim 13 wherein the secondary polymeric binder has pendant ethylenically unsaturated polymerizable groups.
